(19) United States
(12) Patent Application Publication
(10) Pub. No.: US 2026/0019314 A1
(43) Pub. Date: Jan. 15, 2026

(54) CODING SCHEME FOR INSERTING INFORMATION BIT INTO 8B/10B CODED DATA STREAM

(71) Applicant: Analog Devices International Unlimited Company, Limerick (IE)

(72) Inventor: Ning ZHU, Beijing (CN)

(21) Appl. No.: 19/261,776

(22) Filed: Jul. 7, 2025

Related U.S. Application Data
(60) Provisional application No. 63/669,935, filed on Jul. 11, 2024.

(51) Int. Cl. H04L 25/49; H03M 13/09

(52) U.S. Cl. CPC H04L 25/4908; H03M 13/098

(57) ABSTRACT

In an aspect, a method of coding a data stream is provided. In an aspect, the method includes mapping, by a data stream encoder, bits into one or more delimiters for the data stream while limiting a maximum run-length of a same polarity of bits in the data stream to be no more than 5. Each of the one or more delimiters include a zero bit and a one bit appended to an 8b/10b codeword of one or more 8b/10b codewords in the data stream. In an aspect, the method further includes transmitting, by a transmitter, the one or more delimiters in the data stream.

### CROSS REFERENCE

The present application claims priority to U.S. Provisional Patent Application No. 63/669,935, filed on Jul. 11, 2024, the entire contents of which are incorporated herein by reference.

### TECHNICAL FIELD

Aspects of the present disclosure relate generally to 8b/10b line coding and, more particularly, to a coding scheme for inserting an information bit into an 8b/10b coded data stream.

### BACKGROUND

In telecommunications, 8b/10b is a line code that maps 8-bit words to 10-bit symbols to achieve direct current (DC) balance and bounded disparity, and at the same time provide enough state changes to allow reasonable clock recovery. This means that the difference between the counts of ones and zeros in a string of at least 20 bits is no more than two, and that there are not more than five ones or zeros in a row. This helps to reduce the demand for the lower bandwidth limit of the channel necessary to transfer the signal.

In most of the applications, the bit-width of the data payload is in integer multiples of 8, which is good for an efficient 8b/10b coding. However, if an information bit is appended to the data payload, the coding efficiency of the 8b/10b coder may be seriously affected.

### SUMMARY

The following presents a simplified summary of one or more aspects to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detail ended description that is presented later.

In an aspect, a method of coding a data stream is provided. The method includes mapping, by a data stream encoder, bits into one or more delimiters for the data stream while limiting a maximum run-length of a same polarity of bits in the data stream to be no more than 5. Each of the one or more delimiters include a zero bit and a one bit appended to an 8b/10b codeword of one or more 8b/10b codewords in the data stream. The method further includes transmitting, by a transmitter, the one or more delimiters in the data stream.

In another aspect, a system for coding a data stream is provided. The system includes a data stream encoder configured to map bits into one or more delimiters for the data stream while limiting a maximum run-length of a same polarity of bits in the data stream to be no more than 5. Each of the one or more delimiters include a zero bit and a one bit appended to an 8b/10b codeword of one or more 8b/10b codewords in the data stream. The system further includes a transmitter configured to transmit the one or more delimiters in the data stream

To the accomplishment of the foregoing and related ends, the one or more aspects comprise the features hereinafter fully described and particularly pointed out in the claims. The following description and the annexed drawings set forth in detail end certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which.

FIG. 1 is a block diagram illustrating an exemplary 8b/10b system, in accordance with an example aspect.

FIG. 2 is a block diagram illustrating the encoder of the 8b/10b system of FIG. 1, in accordance with an example aspect.

FIG. 3 is a block diagram illustrating the decoder of the 8b/10b system of FIG. 1, in accordance with an example aspect.

FIG. 4 is a block diagram illustrating the insertion of respective delimiters into respective head ends of 8b/10b codewords of an 8b/10b encoded data stream, in accordance with an example aspect.

FIG. 5 is a block diagram illustrating the insertion of respective delimiters into respective tail ends of 8b/10b codewords of an 8b/10b encoded data stream, in accordance with an example aspect.

FIG. 6 is a block diagram illustrating the insertion of respective delimiters into the head ends and tail ends of 8b/10b codewords of an 8b/10b encoded data stream, in accordance with an example aspect.

FIGS. 7-11 are flow diagrams showing a method for coding a data stream, in accordance with example aspect.

### DETAILED DESCRIPTION

Aspects of the present disclosure are directed to a coding scheme for inserting an information bit into an 8b/10b coded data stream to improve the total coding efficiency.

In an aspect, the information bit can be:
part of the data before the 8b/10b encoding;
a parity bit for the 8b/10b codewords;
a parity bit for the data before the 8b/10b encoding; or
any other single bit that needs to transfer or store with the output bit-stream.

In an aspect, the information bit is placed in a first or a second position of a 2-bit delimiter (hereinafter “delimiter”). The delimiter includes a single information bit and another bit having an opposing polarity to the single information bit to direct current (DC) balance the delimiter.

A delimiter can be inserted at a head end and/or a tail end of one or more 8b/10b codewords of an output bit-stream. The delimiters can be decoded independent of the 8b/10b codewords to enable ready identification of the information represented by the information bits of the delimiters.

Thus, in an aspect, the proposed solution maps information bits into delimiters. In an aspect, a delimiter is data structure including a pair of bits, selected as a zero-bit and a one-bit or a one-bit and a zero-bit, that is appended to a head end and/or a tail end of an 8b/10b codeword, while the maximum run-length of the same polarity bits in the 8b/10b codeword is no more than 5. One of the bits in the pair of bits forming a delimiter is an information bit whose value represents a piece of information (e.g., a device feature or status, a communication channel feature or status, and/or a data feature or status) and the other bit in the pair of bits forming the delimiter is a non-information bit whose value has an opposite polarity to the information bit to DC balance the information bit. And, as a result, this convention DC balances the delimiter that includes the information bit and the non-information bit of opposing polarity to the information bit. It is to be appreciated that an information bit can be any value from among 0 or 1, and thus 2 or more consecutive delimiters can include varying information bits selected from both 0 and 1 versus having to maintain a particular pattern or value such as 0 or 1. Thus, a first delimiter can include the values 0,1 while a second delimiter can includes the values 1,0, with either the first bit or the second bit in both delimiters serving as the information bit and the other bit serving as the non-information bit.

TABLE 1 and TABLE 2 below show various values of the information bit and non-information bit in a delimiter according to different conventions. In the convention of TABLE 1, the information bit is the first bit of the delimiter and the non-information bit is the second bit of the delimiter. In the convention of TABLE 2, the information bit is the second bit of the delimiter and the non-information bit is the first bit of the delimiter.

In an aspect, the delimiters are appended to the head end of one or more 8b/10b codewords of a data stream. In another aspect, the delimiters are appended to the tail end of one or more 8b/10b codewords of a data stream. In yet another aspect, the delimiters are appended to both the head end and the tail end of one or more 8b/10b codewords. In still another aspect, the delimiters are appended to a mix of at least any two of: (i) only head ends; (ii) only tail ends; and (iii) both head and tail ends. This mix can be determined dynamically based on the number of information bits that need to be transferred with a given data stream, an available bandwidth for transmitting the data stream, a priority of the data stream, and so forth.

The appended delimiter will keep the DC-balance and maximum run-length properties of the encoded stream, which satisfies the requirement of a standard 8b/10b encoded stream.

### 8b/10b Encoding

In 8b/10b encoding, the 8-bit data payload is encoded into a 10-bit symbol for transmission. The encoding process divides the 8-bit input into two parts:
5b/6b group: The low five bits of the 8-bit data are encoded into a 6-bit group; and
3b/4b group: The top three bits of the 8-bit data are encoded into a 4-bit group.

These two code groups (the 6-bit and the 4-bit groups) are then concatenated together to form the 10-bit symbol that is transmitted on the wire. The bits are sent from least significant bit (LSB) to most significant bit (MSB): a, b, c, d, e, i, f, g, h, and j; meaning the 5b/6b code is sent first, followed by the 3b/4b code.

The following convention is noted:
Upper Case: Upper-case letters (A through H) are used to represent the 8-bit input data to the encoder.
Lower Case: Lower-case letters (a, b, c, d, e, i, f, g, h, j) are used to represent the bits of the 10-bit output symbol that results from the encoding process. Note that the order of the lower-case letters does not follow alphabetical order.

### EXAMPLE

If the 8-bit input data is HGF EDCBA (where A is LSB and His MSB), it is split into:
5b group: A, B, C, D, E
3b group: F, G, H

These two groups (5b group and 3b group) are then encoded separately (based on the current running disparity), and the resulting 6-bit (abcdei) and 4-bit (fghj) groups are combined to form the 10-bit output (abcdeifghj).

To promote coding efficiency, conventional approaches merge an information bit and the data of the next slot before the 8b/10b encoding.

However, in such conventional approaches, once the information bit and the next slot data are merged and 8b/10b encoded, it is impossible to separate them before decoding all the related 8b/10b codewords which contain the information of the information bits.

For example, for a timeslot-based communication system, conventional approaches require a complex buffering and bit re-order scheme to decode the user payload. The decoding latency will also be affected, i.e., increased, which is not acceptable for many real-time applications.

For an 8b/10b encoder, the input data should be byte aligned. Input bit widths other than integer multiples of 8 will cause bandwidth waste.

For the timeslot-based communication system, the data length of each timeslot is usually pre-defined. If using an 8b/10b coding algorithm, the coding efficiency highly depends on the total bit-width of the data in the timeslot.

Aspects of the present disclosure are able to maintain the expected properties of an 8b/10b codeword, including having not more than 5 consecutive bits of the same parity in the 8b/10b codeword. Aspects of the present disclosure maintain the expected properties of an 8b/10b codewords by inserting a DC balanced delimiter at the head end and/or tail end of the 8b/10b codeword. In this way, a single information bit in the delimiter can be retrieved, for example, according to TABLE 1 (or TABLE 2) described herein that can be used for any purpose and that does not require the decoding of the 8b/10b codewords.

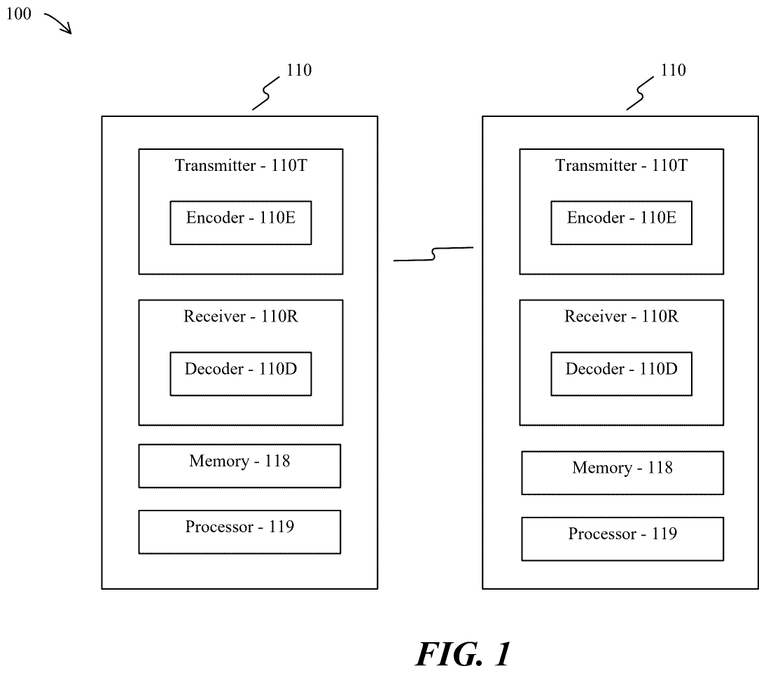

Referring to FIG. 1, an exemplary 8b/10b system 100 is shown, in accordance with an example aspect. In an aspect, the 8b/10b system is used in a high-speed serial interface and/or an optical communication.

The 8b/10b system 100 comprises a plurality of nodes 110. In an aspect, each of the nodes 110 includes a transmitter 110T and a receiver 110R. In an aspect, each transmitter 110T includes an encoder 110E for converting 8-bit data into a 10-bit stream, and each receiver 110R includes a decoder 110D for reversing the process performed by encoder 110E to retrieve the original data (the 8-bit data). In an aspect, encoder 110E and decoder 110D include elements such as buffers, clock data recovery (CDR) units, and serializers/deserializers.

In an aspect, each of the nodes 110 includes one or more processors 119 and one or more memories 118. In an aspect, the one or more memories 118 may store program code for coding a data stream. The program code may include code for forming and appending delimiters to heads and/or tails of code words in a data stream. The program code may be executed by the one or more processors 119.

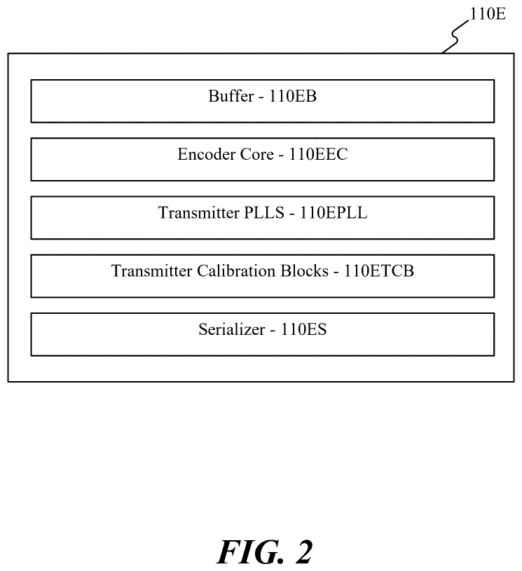

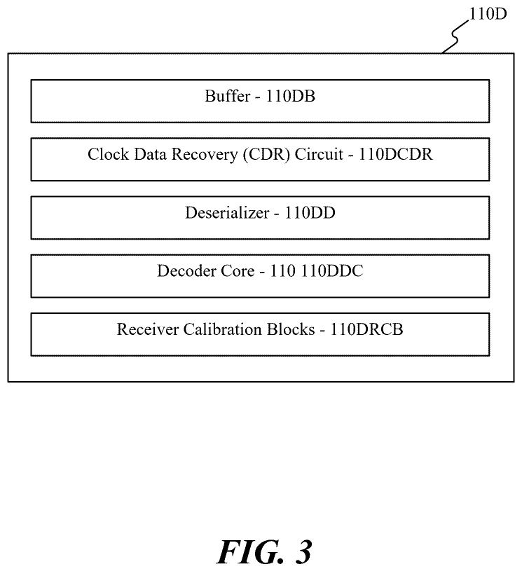

In an aspect, an encoder core 110EEC, described with respect to FIG. 2 below as part of encoder 110E, may include its own one or more processors and one or more memories or may be implemented by one or more processors 119 and one or more memories 118. Similarly, in an aspect, a decoder core 110DDC, described with respect to FIG. 3 below as part of decoder 110D, may include its own one or more processors and one or more memories, may share the same with the encoder 110E, or may be implemented by one or more processors 119 and one or more memories 118. In the latter cases, the one or more processors 119 and the one or more memories may store program code for aiding the encoder 110E and the decoder 110D, including the encoder core 110EEC and the decoder core 110DDC, to encode and decode data streams in accordance with the 8b/10b standard. It is to be appreciated that the appending of the delimiters to the 8b/10b codewords in a data stream is performed to maintain the requirements of the 8b/10b standard. In particular, the mandate that the 8b/10b codewords can have no more than 5 consecutive bits of the same polarity, i.e. a run-length of 5 consecutive equal bits, is readily followed by the various aspects of the present disclosure described herein.

Referring to FIG. 2, an example of encoder 110E of 8b/10b system 100 FIG. 1 is shown, in accordance with an example aspect.

In an aspect, each encoder 110E includes a buffer 110EB, an encoder core 110EEC, transmitter phase locked loops (PLLs) 110EPLL, transmitter calibration blocks 110ETCB, and a serializer 110ES.

Buffer 110EB temporarily stores 8-bit input data before encoding.

Encoder core 110EEC performs the core encoding function, mapping 8 bits to 10 bits.

The mapping involves:
Disparity Control: Maintaining a balance of Os and Is in the output stream to avoid Direct Current (DC) imbalance.
K-Symbols: Using specific “K” symbols for control, synchronization, and error detection.

Disparity control ensures that the encoded data stream has at least a certain amount of data transitions. Without such data transitions, encoding a long stream of 0's or 1's would seem like sending DC through the channel.

In 8b/10b encoding, “K-symbols” are special 10-bit symbols that are used for low-level control functions instead of transmitting 8-bit data. K-symbols are designed to help with synchronization, link establishment, and other tasks that do not involve carrying data. Unlike regular words, K-symbols have specific meanings defined by the protocol using 8b/10b encoding.

Transmitter PLLs 110EPLL provide the clock signal for the encoding process performed by encoder 110E.

Transmitter calibration blocks 110ETCB are used for calibrating the performance of transmitter 110T.

Serializer 110ES converts the parallel 10-bit output into a serial stream.

Referring to FIG. 3, an example of decoder 110D of 8b/10b system 100 FIG. 1 is shown, in accordance with an example aspect.

In an aspect, each decoder 110D includes a buffer 110 DB, a clock data recovery (CDR) circuit 110DCDR, a deserializer 110DD, a decoder core 110DDC, and receiver calibration blocks 110DRCB.

Buffer 110 DB temporarily stores the incoming 10-bitdata stream.

CDR circuit 110CDR extracts the clock signal from the received data stream for decoding.

Receiver deserializer 110DD converts the serial 10-bitstream back into a parallel format.

Decoder core 110DDC performs the inverse mapping of the 8b/10b encoding, recovering the original 8-bit data.

Receiver Calibration Blocks 110DRCB are used for calibrating the performance of the receiver 110R.

TABLE 1 shows a mapping of a single information bit into a delimiter.

TABLE 1

| information bit input | P0 | P1 |
|---|---|---|
| 0 | 0 | 1 |
| 1 | 1 | 0 |

In TABLE 1, the delimiter is comprised of two bits, P0 and P1. Also as shown, in an aspect, the information bit occupies the first position or P0. In other aspects, the information bit can occupy the second position or P1, as shown in TABLE 2. In either case (the information bit occupies the first position or P0 as shown in TABLE 1 or the information bit occupies the second position or P1 as shown in TABLE 2), the other (non-information) bit will have an opposing value to the information bit.

TABLE 2 has the information bit in the second or P1 position, as compared to TABLE 2 having the information bit in the first or P0 position

TABLE 2

| information bit input | P0 | P1 |
|---|---|---|
| 0 | 1 | 0 |
| 1 | 0 | 1 |

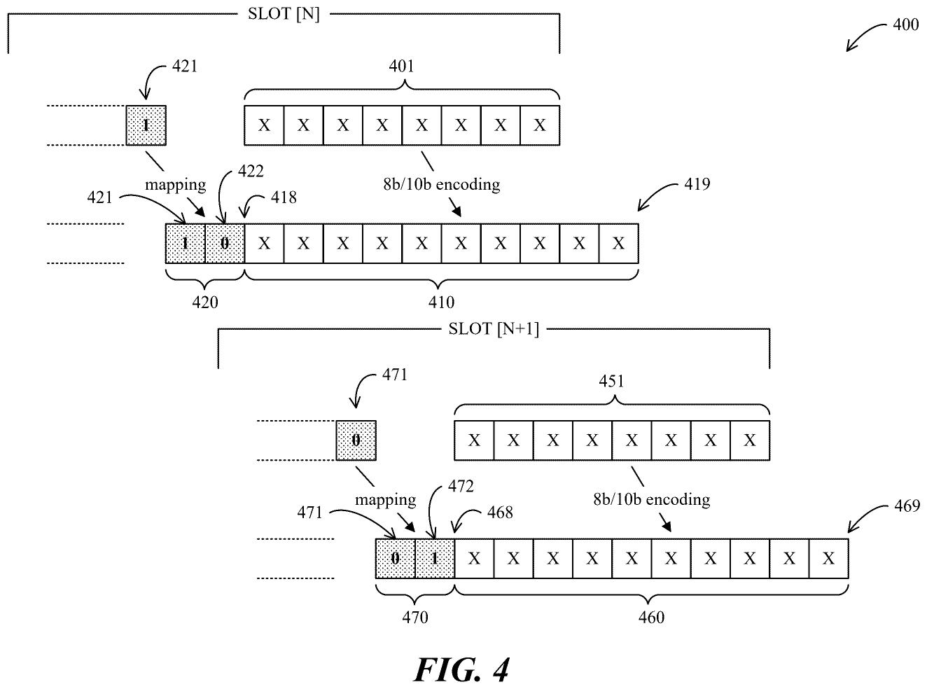

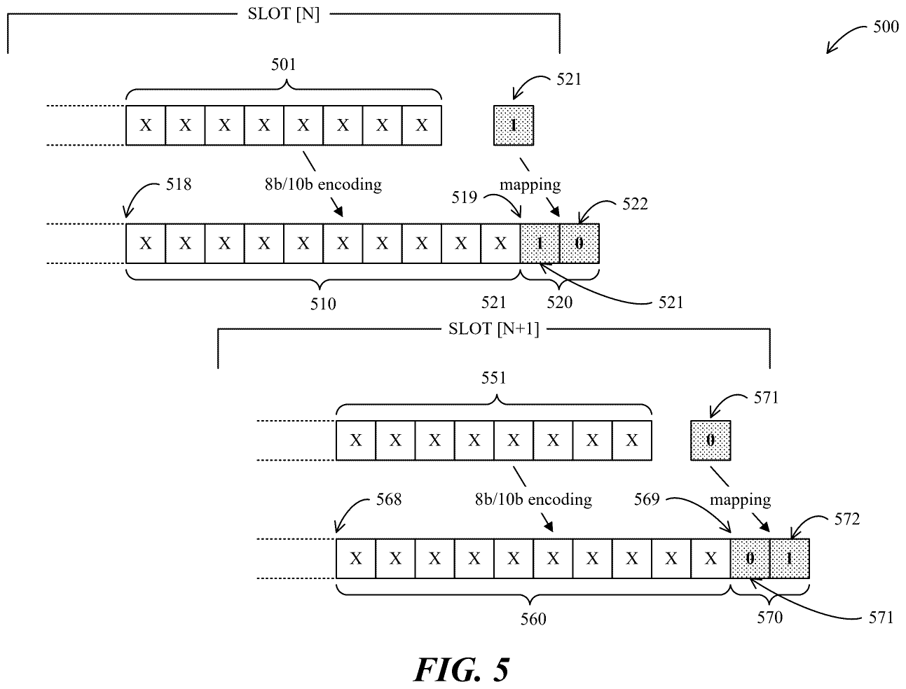

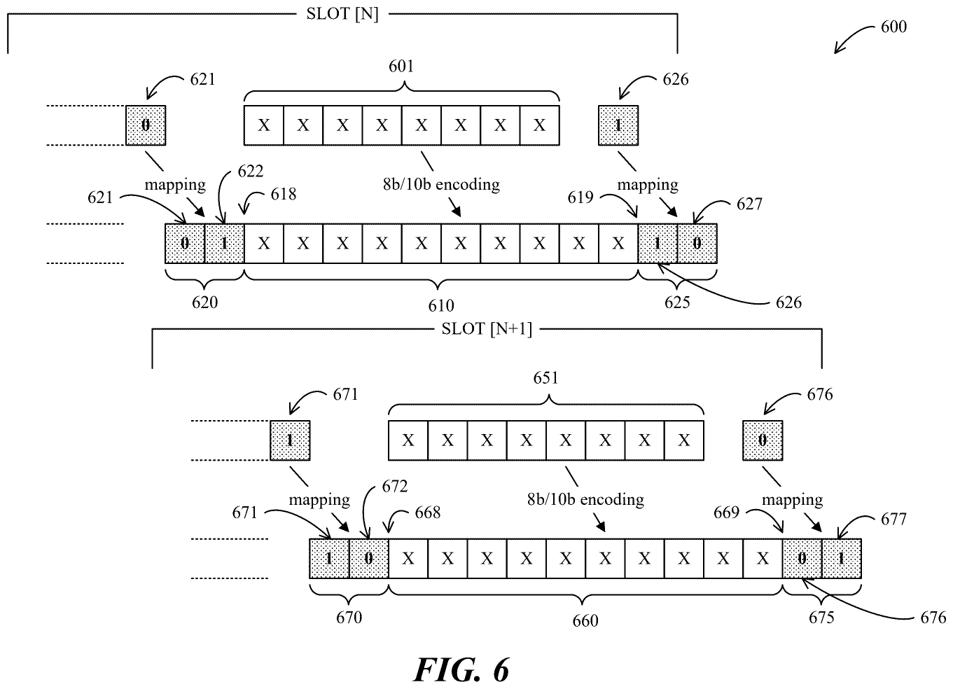

As noted above, one or more delimiters may be appended to an 8b/10b encoded data word. FIGS. 4-6 include examples of various insertions of delimiters. For example, FIG. 4 includes an example of the insertion of respective delimiters at respective head ends of 8b/10b codewords, FIG. 5 includes an example of the insertion of respective delimiters at tail ends of 8b/10b codewords, and FIG. 6 includes an example of the insertion of respective delimiters at both respective head ends and tail ends of 8b/10b codewords. In FIGS. 4-6, reference numerals take the form XYZ, where each X is a respective integer from 0 to 9 representing the corresponding figure number where the element first appears, and each Y and Z represent the specific number for the aspect of a respective Figure.

Referring to FIG. 4, in an example, delimiters 420, 470 are respectively appended to respective head ends 418, 468 of respective 8b/10b codewords 410, 460 of an 8b/10b encoded data stream 400 is shown, in accordance with an example aspect.

### Case Where Information Bit=1 (SLOT N)

An 8-bit data payload 401 is encoded to obtain an 8b/10b codeword 410. The 8b/10b codeword 410 has a head end 418 and a tail end 419.

In an aspect, a delimiter 420 is appended to the head end 418 of the 8b/10b codeword 410. The delimiter 420 includes an information bit 421 equal to 1 and another bit 422 equal to 0.

In an aspect, the value of the other bit 422 and the positions of the information bit 421 and the other bit 422 in the delimiter 420 are determined using TABLE 1. For example, as seen in the second row of TABLE 1, for an information bit value of 1, the single information bit is placed in the first position or P0 of the delimiter 420 and the other bit equal to 0 is placed in the second position or P1 of the delimiter 420.

In another aspect, the value of the other bit 422 and the positions of the information bit 421 and the other bit 422 in the delimiter 420 are determined using TABLE 2.

### Case Where Information Bit=0 (SLOT N+1)

An 8-bit data payload 451 is encoded to obtain an 8b/10b codeword 460. The 8b/10b codeword 460 has a head end 468 and a tail end 469.

In an aspect, a delimiter 470 is appended to the head end 468 of the 8b/10b codeword 460. The delimiter 470 includes an information bit 471 equal to 1 and another bit 472 equal to 0.

In an aspect, the value of the other bit 472 and the positions of the information bit 471 and the other bit 472 in the delimiter 470 are determined using TABLE 1. For example, as seen in the second row of TABLE 1, for an information bit value of 1, the single information bit is placed in the first position or P0 of the delimiter 470 and the other bit equal to 0 is placed in the second position or P1 of the delimiter 470.

In another aspect, the value of the other bit 472 and the positions of the information bit 471 and the other bit 472 in the delimiter 470 are determined using TABLE 2.

In an aspect, conventional 8b/10b encoding can be performed on the 8-bit data payloads 401, 451 to respectively obtain the 8b/10b codewords 410, 460, without considering the existence of the single information bit or the delimiter that contains the single information bit.

For slots N and N+1, it can be seen that even in the worst case, the run-length of 5 consecutive equal bits is still satisfied.

The delimiter itself (e.g., delimiters 420, 470) is zero and one alternated, so the delimiter is direct current (DC) balanced. Hence, respectively appending the delimiters 420, 470 to the head ends 418, 468 of the 8b/10b codewords 410, 460 will not hurt the DC balance properties of the 8b/10b codewords 410, 460.

Referring to FIG. 5, in an example, delimiters 520, 570 are respectively appended to respective tail ends 519, 569 of respective 8b/10b codewords 510, 560 of an 8b/10b data stream 500 is shown, in accordance with an example aspect.

### Case Where Information Bit=1 (SLOT N)

An 8-bit data payload 501 is encoded to obtain an 8b/10b codeword 510. The 8b/10b codeword 510 has a head end 518 and a tail end 519.

In an aspect, a delimiter 520 is appended to the tail end 519 of the 8b/10b codeword 510. The delimiter 520 includes an information bit 521 equal to 1 and another bit 522 equal to 0.

In an aspect, the value of the other bit 522 and the positions of the information bit 521 and the other bit 522 in the delimiter 520 are determined using TABLE 1. For example, as seen in the second row of TABLE 1, for an information bit value of 1, the single information bit is placed in the first position or PO of the delimiter 520 and the other bit equal to 0 is placed in the second position or P1 of the delimiter 520.

In another aspect, the value of the other bit 522 and the positions of the information bit 521 and the other bit 522 in the delimiter 520 are determined using TABLE 2.

### Case Where Information Bit=0 (SLOT N+1)

An 8-bit data payload 551 is encoded to obtain an 8b/10b codeword 560. The 8b/10b codeword 560 has a head end 568 and a tail end 569.

In an aspect, a delimiter 570 is appended to the tail end 569 of the 8b/10b codeword 560. The delimiter 570 includes an information bit 571 equal to 1 and another bit 572 equal to 0.

In an aspect, the value of the other bit 572 and the position of the information bit 571 and the other bit 572 in the delimiter 570 are determined using TABLE 1. For example, as seen in the second row of TABLE 1, for an information bit value of 1, the single information bit is placed in the first position or P0 of the delimiter 570 and the other bit equal to 0 is placed in the second position or P1 of the delimiter 570.

In another aspect, the value of the other bit 572 and the positions of the information bit 571 and the other bit 572 in the delimiter 570 are determined using TABLE 2.

In an aspect, conventional 8b/10b encoding can be performed on the 8-bit data payloads 501, 551 to respectively obtain the 8b/10b codewords 510, 560, without considering the existence of the single information bit or the delimiter that contains the single information bit.

For slots N and N+1, it can be seen that even in the worst case, the run-length of 5 consecutive equal bits is still satisfied.

The delimiter itself (e.g., each of delimiters 520, 570) is zero and one alternated, so the delimiter is direct current (DC) balanced. Hence, respectively appending the delimiters 520, 570 to the tail ends 519, 569 of the 8b/10b codewords 510, 560 will not hurt the DC balance properties of the 8b/10b codewords 510, 560.

Referring to FIG. 6, in an example, delimiters 620, 670 are respectively appended to respective head ends 618, 668 of respective 8b/10b codewords 610, 660 of an 8b/10b encoded data stream 600 and delimiters 625, 675 being respectively appended to respective tail ends 619, 669 of respective 8b/10b codewords 610, 660 is shown, in accordance with an example aspect.

### Case Where Information Bits=0 and 1 (SLOT N)

An 8-bit data payload 601 is encoded to obtain an 8b/10b codeword 610. The 8b/10b codeword 610 has a head end 618 and a tail end 619.

In an aspect, a delimiter 620 is appended to the head end 618 of the 8b/10b codeword 610, and a delimiter 625 is appended to the tail end 619 of the 8b/10b codeword 610. Delimiter 620 includes an information bit 621 equal to 0 and another bit 622 equal to 1. Delimiter 625 includes an information bit 626 equal to 1 and another bit 627 equal to 0.

In an aspect, the values of the other bits 622, 627 and the positions of the information bits 621, 626 and the other bits 622, 627 are determined using TABLE 1. For example, as seen in the second row of TABLE 1, for an information bit value of 0, the single information bit is placed in the first position or P0 of the delimiter 620 and the other bit equal to 1 is placed in the second position or P1 of the delimiter 620. As seen in the third row of TABLE 1, for an information bit value of 1, the single information bit is placed in the first position or P0 of the delimiter 670 and the other bit equal to 0 is placed in the second position or P1 of the delimiter 670.

In another aspect, the value of the other bits 622, 627 and the positions of the information bits 621, 626 and the other bits 622, 627 in the delimiters 620, 625 are determined using TABLE 2.

### Case Where Information Bit=1 and 0 (SLOT N+1)

An 8-bit data payload 651 is encoded to obtain an 8b/10b codeword 660. The 8b/10b codeword 660 has a head end 668 and a tail end 669.

In an aspect, a delimiter 670 is appended to the head end 668 of the 8b/10b codeword 660, and a delimiter 675 is appended to the tail end 669 of the 8b/10b codeword 660. Delimiter 670 includes an information bit 671 equal to 1 and another bit 672 equal to 0. Delimiter 675 includes an information bit 676 equal to 0 and another bit 677 equal to 1. In an aspect, the values of the other bit 672 and 677 in both delimiter 670 and delimiter 675 are determined using TABLE 1.

In another aspect, the value of the other bits 672, 677 and the positions of the information bits 671, 676 and the other bits 672, 677 in the delimiters 670, 675 are determined using TABLE 2.

In an aspect, conventional 8b/10b encoding can be performed on the 8-bit data payloads 601, 651 to respectively obtain the 8b/10b codewords 610, 660, without considering the existence of the information bits or the delimiters that contains the information bits.

For slots N and N+1, it can be seen that even in the worst case, the run-length of 5 consecutive equal bits is still satisfied.

The delimiter itself (e.g., any of delimiters 620, 625, 670, 675) is zero and one alternated, so the delimiter is direct current (DC) balanced. Hence, respectively appending the delimiters 620, 670 to the head ends 618 of the 8b/10b codewords 610, 660 and respectively appending the delimiters 625, 675 to the tail ends 618, 668 of the 8b/10b codewords 610, 660 will not hurt the DC balance properties of the 8b/10b codewords 610, 660.

While a 0, 1 and a 1, 0 were used for the values of the information bits for the first case (slot N) and second case (slot N+1), in other aspects, any values may be used for the information bits for the head end and tail end of an codeword including 0, 0; 0, 1; 1, 0; and 1, 1.

Thus, to implement the delimiter at the head end or tail end, or head end and tail end, of an 8b/10b codeword as per FIGS. 4, 5, and 6, respectively, a single 8b/10b codeword has a maximum run-length of 4 for the same polarity bits at its head end or tail end depending on delimiter position. That is, if the delimiter is placed at the head end, then the maximum run-length of 4 for the same polarity bits applies to the head end. In contrast, if the delimiter is placed at the tail end, then the maximum run-length of 4 for the same polarity bits applies to the tail end.

To implement respective delimiters at the head end and the tail end of an 8b/10b codeword, since a delimiter is placed at the head end and the tail end, then the maximum run-length of 4 for the same polarity bits applies to the head end and the tail end.

Thus, if the delimiter has the property of containing an alternating 0 and 1 or 1 and 0 at the head end and/or tail end, the delimiter also has the property of limiting the maximum run-length itself at that end to be less than 5. As can be appreciated, once appended to the head end or tail end, the delimiter will never break the maximum run-length property of the original 8b/10b encoded data stream of not containing more than 5 consecutive bits of the same polarity.

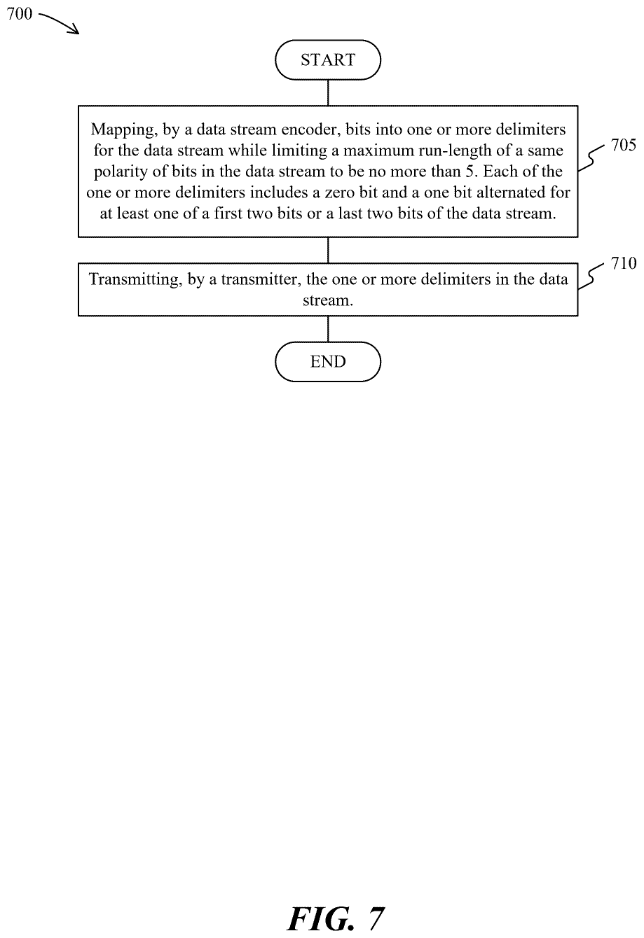

Referring now to FIGS. 7-10, one example of a method 700 for coding a data stream such as, e.g., data stream 400 of FIG. 4, data stream 500 of FIG. 5, and/or data stream 600 of FIG. 6 is shown, in accordance with example aspect. Boxes shown in dashes or dashes and dots are optional features.

Method 700 may be performed by one or more nodes (e.g., one or more nodes 110 of FIG. 1). The method 700 may be implemented, in part, by encoder core 110EEC of data stream encoder 110E of FIG. 2 and computer code (e.g., stored in buffer 110EB of data stream encoder 110E of FIG. 2).

Referring now to FIGS. 1-2 and FIGS. 4-7, at block 705, the method 700 includes mapping, by a data stream encoder 110E (FIGS. 1-2), bits into one or more delimiters 420, 470 (FIG. 4), 520, 570 (FIG. 5), 620, 625, 670, 675 (FIG. 6) for the data stream 400, 500, 600 while limiting a maximum run-length of a same polarity of bits in the data stream 400, 500, 600 to be no more than 5. Each of the one or more delimiters 420, 470, 520, 570, 620, 625, 670, 675 includes a zero bit 422, 471, 522, 571, 621, 627, 672, 676 and a one bit 421, 472, 521, 572, 622, 626, 671, 677 appended to a codeword 410, 460, 510, 560, 610, 660 of one or more codewords 410, 460, 510, 560, 610, 660 in the data stream 400, 500, 600.

Any of the zero bit 422, 471, 522, 571, 621, 627, 672, 676 or the one bit 421, 472, 521, 572, 622, 626, 671, 677 can be designated as the information bit that conveys 1-bit of information, as either a 0 or a 1. To direct current (DC) balance the information bit, an opposing polarity bit is appended to the information bit of the delimiter.

In an aspect, any number of delimiters may be used, depending on various criteria such as encoder capability (e.g., processing power, memory, and so forth), available bandwidth, decoder capability (e.g., processing power, memory, and so forth), and so forth.

At block 710, the method 700 includes transmitting, by a transmitter, the one or more delimiters 420, 470, 520, 570, 620, 625, 670, 675 in the data stream 400, 500, 600.

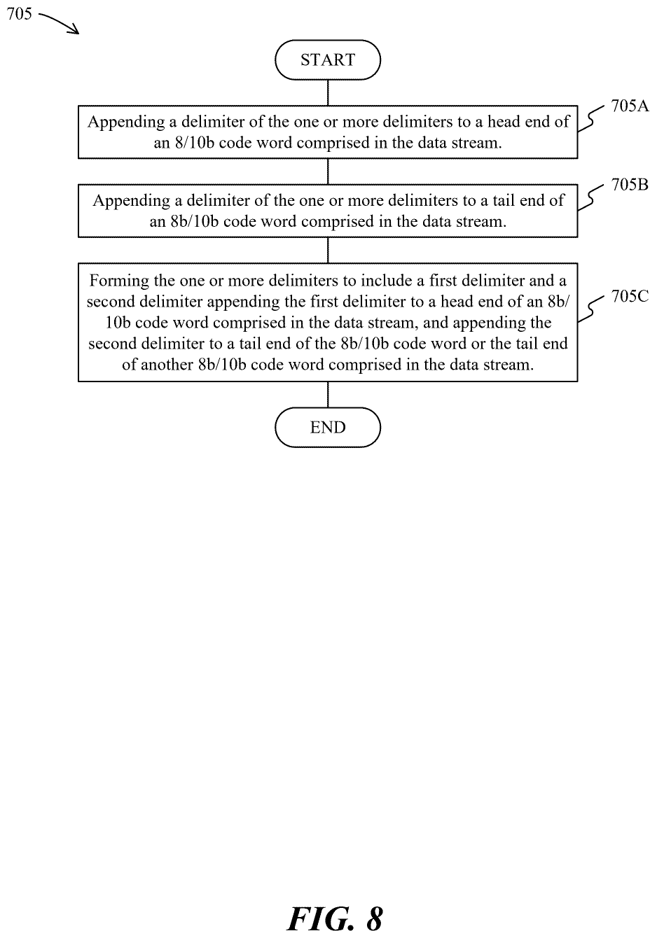

Referring now to FIGS. 8, further optional blocks of method 700 of FIG. 7 are shown, in accordance with an example aspect. The further blocks relate to block 705 with respect to the placing of the delimiter in the data stream.

In an aspect, block 705 includes one or more of block 705A (FIG. 4—delimiters appended to head ends of 8b/10b codewords), block 705B (FIG. 5—delimiters appended to tail ends of 8b/10b codewords), or block 705C (FIG. 6—delimiters appended to both head ends and tail ends of 8b/10b codewords).

At block 705A, the method 700 includes appending a delimiter 420, 470 of the one or more delimiters 420, 470 to a head end 418, 468 of an 8/10b codeword 410, 460 comprised in the data stream 400. In particular, in an aspect as shown in FIG. 4, delimiter 420 is appended to head end 418 of 8b/10b codeword 410, and delimiter 470 is appended to head end 468 of 8b/10b codeword 460.

At block 705B, alternatively or in addition, the method 700 includes appending a delimiter 520, 570 of the one or more delimiters 520, 570 to a tail end 519, 569 of an 8b/10b codeword 510, 560 comprised in the data stream 500. In particular, in an aspect as shown in FIG. 5, delimiter 520 is appended to tail end 519 of 8b/10b codeword 510, and delimiter 570 is appended to tail end 569 of 8b/10b codeword 560.

At block 705C, alternatively or in addition, the method 700 includes forming the one or more delimiters 620, 670, 625, 675 to include a first delimiter 620, 670 and a second delimiter 625, 675, appending the first delimiter 620 to a head end 618 of an 8b/10b codeword 610 comprised in the data stream 600, and appending the second delimiter 625 to a tail end 619 of the 8b/10b codeword 610 or the tail end 669 of another 8b/10b codeword 660 comprised in the data stream 600. In particular, in an aspect as shown in FIG. 6, delimiter 620 is appended to head end 618 of 8b/10b codeword 610, and delimiter 625 is appended to tail end 669 of 8b/10b codeword 660, delimiter 670 is appended to head end 668 of 8b/10b codeword 660, and delimiter 675 is appended to tail end 669 of 8b/10b codeword 660. In this way, each 8b/10b codeword 610 and 660 in data stream 600, in having a delimiter with a respective information bit at both the head end and tail end, includes double the number of information bits compared to each 8b/10b codeword 410 and 460 in data stream 400 and each 8b/10b codeword 510, and 560 in data stream 500 which only have a single delimiter at the tail end (in the case of codewords 410 and 460) or at the head end (in the case of codewords 510, 560).

In an aspect, delimiters in groups of multiples (e.g., 8, 16, 24, and so forth) of eight can be appended to a number of codewords spanning from 4 to 8 to provide one or more bytes of information in an 8b/10b decoded data stream. In an aspect, the values of the delimiter bits can be determined independent of having to decode the 8b/10b codewords to which the delimiters are appended as well as independent of having to decode other 8b/10b codewords that do not have delimiters appended thereto in the data stream. In this way, one or more information bits can be included in and conveyed with an 8b/10b data stream, where the information bits are included in 2-bit delimiters that include a single information bit and a single opposing polarity DC balancing bit.

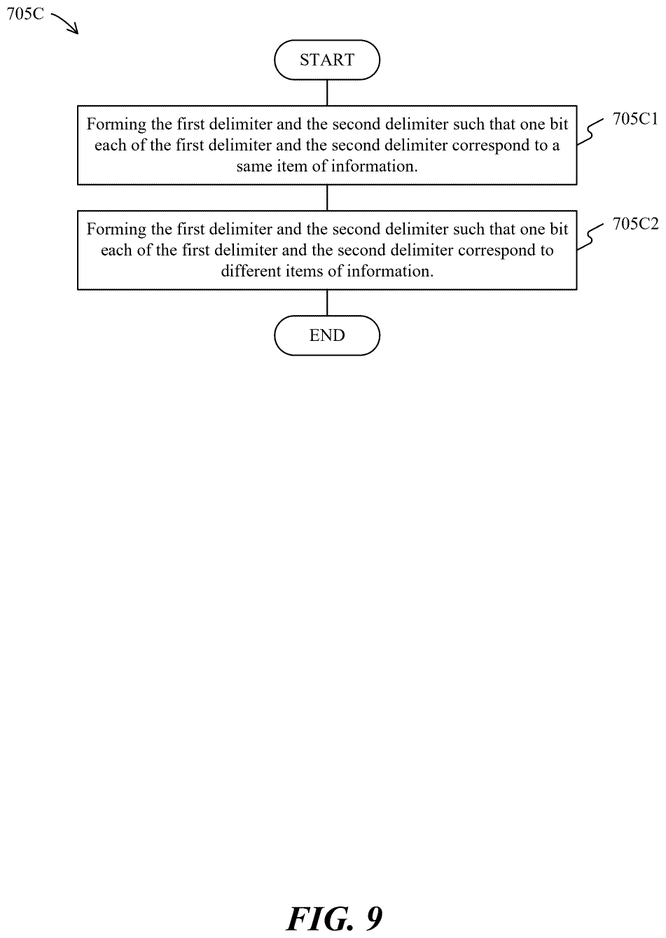

Referring now to FIG. 9, further optional blocks of method 700 of FIG. 7 are shown, in accordance with an example aspect. The further blocks relate to block 705C and the information that can be represented by the information bit included in a delimiter.

In an aspect, the block 705C may include one or more of blocks 705C1 and/or 705C2.

At block 705C1, the method 700 includes forming the first delimiter 620, 670 and the second delimiter 625, 675 such that one bit each of the first delimiter 620, 670 and the second delimiter 625, 675 correspond to a same item of information.

For example, each delimiter includes an information bit and a DC balanced bit. In the case of block 705C1, the first delimiter 620, 670 and the second delimiter 625, 675 may be formed such that the information bit in each of the first delimiter 620, 670 and the second delimiter 625, 675 respectively correspond to a first feature and a second feature of a same item. For example, items can relate to an encoder feature and/or encoder status, a communication channel feature and/or communication channel status, and/or a data feature (e.g., parity) and/or data status (e.g., priority), before or after coding. The encoder feature and/or status may include encoder processing capability, available memory, and so forth. For example, an information bit having a value of 1 may indicate one set of capabilities with respect to processing capability and available memory, and a value of 0 may indicate a different set of capabilities with respect to processing capability and available memory. The communication channel features and/or status may include a currently available bandwidth or an expected available bandwidth. For example, an information bit having a value of 0 may indicate a first available bandwidth value and an information bit having a value of 1 may indicate a second available bandwidth value.

At block 705C2, alternatively or in addition, the method 700 includes forming the first delimiter 620, 670 and the second delimiter 625, 675 such that one bit each of the first delimiter 620, 670 and the second delimiter 625, 675 correspond to different items of information. In this way, information bits corresponding to different items of information can be appended to 8b/10b code words to enable the information to be ascertained on a decoder side without having to decode the appended 8b/10b codeword.

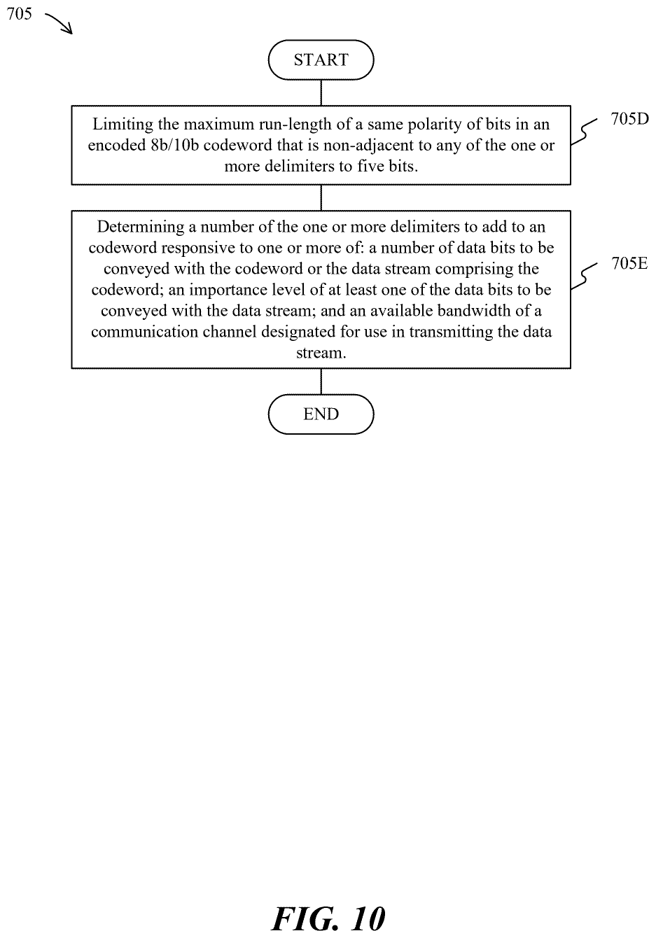

Referring now to FIG. 10, further optional blocks of method 700 of FIG. 7 are shown, in accordance with an example aspect. The further blocks relate to block 705 and limiting the maximum run-length of a same polarity of bits in an 8b/10b codeword.

At block 705D, the method 700 includes limiting the maximum run-length of a same polarity of bits in an 8b/10b codeword 410, 460, 510, 560, 610, 660 that is adjacent to any of the one or more delimiters 420, 470, 520, 570, 620, 670, 625, 675 to four bits. This accounts for a bit of a delimiter adjacent to four bits of an encoded 8b/10b codeword having a same polarity as the four bits to ensure the maximum run-length of 5 consecutive bits of the same polarity is not exceeded.

At block 705E, the method 700 includes limiting the maximum run-length of a same polarity of bits in an 8b/10b codeword that is non-adjacent to any of the one or more delimiters to five bits. This allows the maximum permitted run-length to not be exceeded when a delimiter is not adjacent to an 8b/10b codeword.

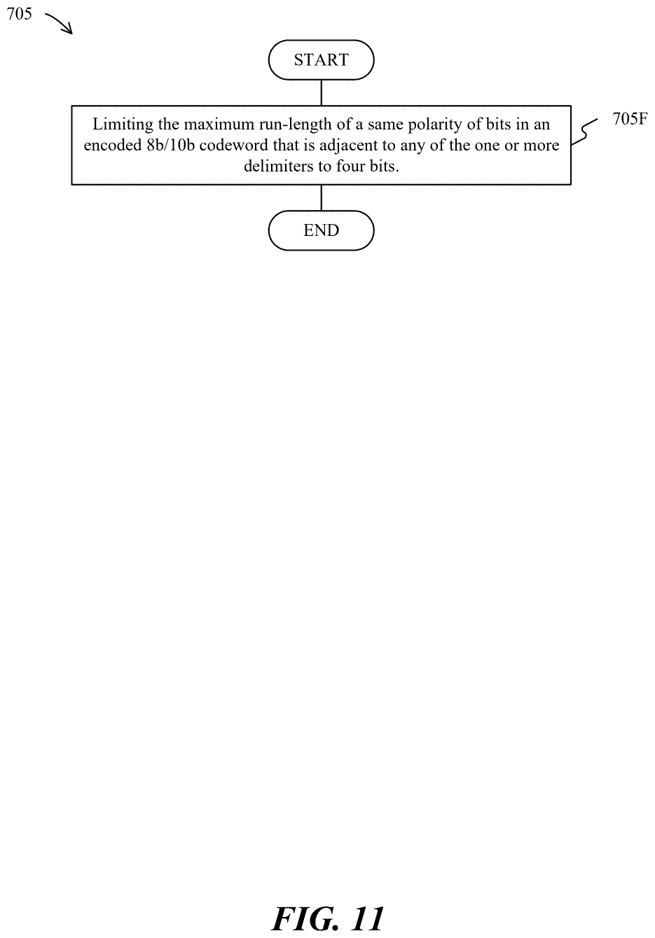

Referring now to FIG. 11, a further optional block of method 700 of FIG. 7 is shown, in accordance with an example aspect. The further block relates to block 705 and determining how many delimiters to add to an 8b/10b data stream.

At block 705F, the method 700 includes determining a number of the one or more delimiters 420, 470, 520, 570, 620, 670, 625, 675 to add to an codeword 410, 460, 510, 560, 610, 660 responsive to one or more of: a number of data bits to be conveyed with the codeword 410, 460, 510, 560, 610, 660 or the data stream 400, 500, 600 comprising the codeword 410, 460, 510, 560, 610, 660; an importance level of at least one of the data bits to be conveyed with the data stream 400, 500, 600; and an available bandwidth of a communication channel designated for use in transmitting the data stream 400, 500, 600. In this way, various criteria can be used to determine how to allocate the delimiters in a data stream.

Additional aspects of the present disclosure may include one or more of the following clauses.

Clause 1. A method of coding a data stream, comprising: mapping, by a data stream encoder, bits into one or more delimiters for the data stream while limiting a maximum run-length of a same polarity of bits in the data stream to be no more than 5, wherein each of the one or more delimiters comprise a zero bit and a one bit appended to an 8b/10b codeword of one or more 8b/10b codewords in the data stream; and transmitting, by a transmitter, the one or more delimiters in the data stream.

Clause 2. The method in accordance with clause 1, further comprising appending a delimiter of the one or more delimiters to a head end of the 8b/10b codeword comprised in the data stream.

Clause 3. The method in accordance with any preceding clause, further comprising appending a delimiter of the one or more delimiters to a tail end of the 8b/10b codeword comprised in the data stream.

Clause 4. The method in accordance with any preceding clause, wherein the one or more delimiters comprise a first delimiter and a second delimiter, and the method further comprises: appending the first delimiter to a head end of the 8b/10b codeword comprised in the data stream; and appending the second delimiter to a tail end of the 8b/10b codeword or a tail end of another 8b/10b codeword comprised in the data stream.

Clause 5. The method in accordance with any preceding clause, wherein one bit each of the first delimiter and the second delimiter correspond to a same item of information.

Clause 6. The method in accordance with any preceding clause, wherein one bit each of the first delimiter and the second delimiter correspond to different items of information.

Clause 7. The method in accordance with any preceding clause, wherein each of the one or more delimiters includes a data bit for representing an item of information to be transferred with the data stream and a direct current (DC) balancing bit configured to provide DC balance to the data stream.

Clause 8. The method in accordance with any preceding clause, wherein one of the zero bit or the one bit of a delimiter of the one or more delimiters is a parity bit for the one or more 8b/10b codewords comprised in the data stream.

Clause 9. The method in accordance with any preceding clause, wherein mapping bits into one or more delimiters for the data stream comprises limiting the maximum run-length of a same polarity of bits in an 8b/10b codeword that is adjacent to any of the one or more delimiters to four bits.

Clause 10. The method in accordance with any preceding clause, wherein mapping bits into one or more delimiters for the data stream comprises limiting the maximum run-length of a same polarity of bits in an 8b/10b codeword that is non-adjacent to any of the one or more delimiters to five bits.

Clause 11. The method in accordance with any preceding clause, further comprising determining a number of the one or more delimiters to add to the 8b/10b codeword responsive to one or more of: a number of data bits to be conveyed with the 8b/10b codeword or the data stream comprising the 8b/10b codeword; an importance level of at least one of the bits to be conveyed with the data stream; and an available bandwidth of a communication channel designated for use in transmitting the data stream.

Clause 12. A system for coding a data stream, comprising: a data stream encoder configured to map bits into one or more delimiters for the data stream while limiting a maximum run-length of a same polarity of bits in the data stream to be no more than 5, wherein each of the one or more delimiters comprise a zero bit and a one bit appended to an 8b/10b codeword of one or more 8b/10b codewords in the data stream; and a transmitter configured to transmit the one or more delimiters in the data stream.

Clause 13. The system in accordance with clause 12, wherein the data stream encoder is further configured to append a delimiter of the one or more delimiters to a head end of the 8b/10b codeword comprised in the data stream.

Clause 14. The system in accordance with any preceding clause, further comprising appending a delimiter of the one or more delimiters to a tail end of the 8b/10b codeword comprised in the data stream.

Clause 15. The system in accordance with any preceding clause, wherein the one or more delimiters comprise a first delimiter and a second delimiter, and the data stream encoder is further configured to: append the first delimiter to a head end of the 8b/10b codeword comprised in the data stream; and append the second delimiter to a tail end of the 8b/10b codeword or a tail end of another 8b/10b codeword comprised in the data stream.

Clause 16. The system in accordance with any preceding clause, wherein one bit each of the first delimiter and the second delimiter correspond to a same item of information.

Clause 17. The system in accordance with any preceding clause, wherein one bit each of the first delimiter and the second delimiter correspond to different items of information.

Clause 18. The system in accordance with any preceding clause, wherein each of the one or more delimiters includes a data bit for representing an item of information to be transferred with the data stream and a direct current (DC) balancing bit configured to provide DC balance to the data stream.

Clause 19. The system in accordance with any preceding clause, wherein one of the zero bit or the one bit of a delimiter of the one or more delimiters is a parity bit for one or more 8b/10b codewords comprised in the data stream.

Clause 20. The system in accordance with any preceding clause, wherein the data stream encoder is configured to limit the maximum run-length of a same polarity of bits in an 8b/10b codeword that is adjacent to any of the one or more delimiters to four bits.

Clause 21. The system in accordance with any preceding clause, wherein the data stream encoder is configured to limit the maximum run-length of a same polarity of bits in an 8b/10b codeword that is non-adjacent to any of the one or more delimiters to five bits.

Clause 22. The system in accordance with any preceding clause, wherein the data stream encoder is further configured to determine a number of the one or more delimiters to add to the 8b/10b codeword responsive to one or more of: a number of data bits to be conveyed with the 8b/10b codeword or the data stream comprising the 8b/10b codeword; an importance level of at least one of the bits to be conveyed with the data stream; and an available bandwidth of a communication channel designated for use in transmitting the data stream.

Various aspects of the disclosure may take the form of an entirely or partially hardware aspect, an entirely or partially software aspect, or a combination of software and hardware. Furthermore, as described herein, various aspects of the disclosure (e.g., systems and methods) may take the form of a computer program product comprising a computer-readable non-transitory storage medium having computer-accessible instructions (e.g., computer-readable and/or computer-executable instructions) such as computer software, encoded or otherwise embodied in such storage medium. Those instructions can be read or otherwise accessed and executed by one or more processors to perform or permit the performance of the operations described herein. The instructions can be provided in any suitable form, such as source code, compiled code, interpreted code, executable code, static code, dynamic code, assembler code, combinations of the foregoing, and the like. Any suitable computer-readable non-transitory storage medium may be utilized to form the computer program product. For instance, the computer-readable medium may include any tangible non-transitory medium for storing information in a form readable or otherwise accessible by one or more computers or processor(s) functionally coupled thereto. Non-transitory storage media can include read-only memory (ROM); random access memory (RAM); magnetic disk storage media; optical storage media; flash memory, and so forth.

Aspects of this disclosure are described herein with reference to block diagrams and flowchart illustrations of methods, systems, apparatuses, and computer program products. It can be understood that each block of the block diagrams and flowchart illustrations, and combinations of blocks in the block diagrams and flowchart illustrations, respectively, can be implemented by computer-accessible instructions. In certain implementations, the computer-accessible instructions may be loaded or otherwise incorporated into a general-purpose computer, a special-purpose computer, or another programmable information processing apparatus to produce a particular machine, such that the operations or functions specified in the flowchart block or blocks can be implemented in response to execution at the computer or processing apparatus.

Unless otherwise expressly stated, it is in no way intended that any protocol, procedure, process, or method set forth herein be construed as requiring that its acts or steps be performed in a specific order. Accordingly, where a process or method claim does not actually recite an order to be followed by its acts or steps, or it is not otherwise specifically recited in the claims or descriptions of the subject disclosure that the steps are to be limited to a specific order, it is in no way intended that an order be inferred, in any respect. This holds for any possible non-express basis for interpretation, including: matters of logic with respect to the arrangement of steps or operational flow; plain meaning derived from grammatical organization or punctuation; the number or type of aspects described in the specification or annexed drawings; or the like.

As used in this disclosure, including the annexed drawings, the terms “component,” “module,” “system,” and the like are intended to refer to a computer-related entity or an entity related to an apparatus with one or more specific functionalities. The entity can be either hardware, a combination of hardware and software, software, or software in execution. One or more of such entities are also referred to as “functional elements.” As an example, a component can be a process running on a processor, a processor, an object, an executable, a thread of execution, a program, and/or a computer. For example, both an application running on a server or network controller, and the server or network controller can be a component. One or more components can reside within a process and/or thread of execution and a component can be localized on one computer and/or distributed between two or more computers. Also, these components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which parts can be controlled or otherwise operated by program code executed by a processor. As yet another example, a component can be an apparatus that provides specific functionality through electronic components without mechanical parts, the electronic components can include a processor to execute program code that provides, at least partially, the functionality of the electronic components. As still another example, interface(s) can include I/O components or Application Programming Interface (API) components. While the foregoing examples are directed to aspects of a component, the exemplified aspects or features also apply to a system, module, and similar.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in this specification and annexed drawings should be construed to mean “one or more” unless specified otherwise or clear from context to be directed to a singular form.

In addition, the terms “example” and “such as” and “e.g.” are utilized herein to mean serving as an instance or illustration. Any aspect or design described herein as an “example” or referred to in connection with a “such as” clause or “e.g.” is not necessarily to be construed as preferred or advantageous over other aspects or designs described herein. Rather, use of the terms “example” or “such as” or “e.g.” is intended to present concepts in a concrete fashion. The terms “first,” “second,” “third,” and so forth, as used in the claims and description, unless otherwise clear by context, is for clarity only and does not necessarily indicate or imply any order in time or space.

The term “processor,” as utilized in this disclosure, can refer to any computing processing unit or device comprising processing circuitry that can operate on data and/or signaling. A computing processing unit or device can include, for example, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can include an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. In some cases, processors can exploit nano-scale architectures, such as molecular and quantum-dot based transistors, switches and gates, in order to optimize space usage or enhance performance of user equipment. A processor may also be implemented as a combination of computing processing units.

In addition, terms such as “store,” “data store,” data storage,” “database,” and substantially any other information storage component relevant to operation and functionality of a component, refer to “memory components,” or entities embodied in a “memory” or components comprising the memory. It will be appreciated that the memory components described herein can be either volatile memory or nonvolatile memory or can include both volatile and nonvolatile memory. Moreover, a memory component can be removable or affixed to a functional element (e.g., device, server).

Simply as an illustration, nonvolatile memory can include read only memory (ROM), programmable ROM (PROM), electrically programmable ROM (EPROM), electrically erasable ROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

The term “article of manufacture” as used herein is intended to encompass a computer program accessible from any non-transitory computer-readable device, carrier, or media. For example, computer readable media can include but are not limited to magnetic storage devices (e.g., hard drive disk, floppy disk, magnetic strips, or similar), optical discs (e.g., compact disc (CD), digital versatile disc (DVD), Blu-ray disc (BD), or similar), smart cards, and flash memory devices (e.g., card, stick, key drive, or similar).

The detail ended description set forth herein in connection with the annexed figures is intended as a description of various configurations or implementations and is not intended to represent the only configurations or implementations in which the concepts described herein may be practiced. The detail ended description includes specific detail ends for the purpose of providing a thorough understanding of various concepts. However, it will be apparent to those skilled in the art that these concepts may be practiced without these specific detail ends or with variations of these specific detail ends. In some instances, well-known components are shown in block diagram form, while some blocks may be representative of one or more well-known components.

The previous description of the disclosure is provided to enable a person skilled in the art to make or use the disclosure. Various modifications to the disclosure will be readily apparent to those skilled in the art, and the common principles defined herein may be applied to other variations without departing from the scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A method of coding a data stream, comprising:
mapping, by a data stream encoder, bits into one or more delimiters for the data stream while limiting a maximum run-length of a same polarity of bits in the data stream to be no more than 5, wherein each of the one or more delimiters comprise a zero bit and a one bit appended to an 8b/10b codeword of one or more 8b/10b codewords in the data stream; and
transmitting, by a transmitter, the one or more delimiters in the data stream.

2. The method in accordance with claim 1, further comprising appending a delimiter of the one or more delimiters to a head end of the 8b/10b codeword comprised in the data stream.

3. The method in accordance with claim 1, further comprising appending a delimiter of the one or more delimiters to a tail end of the 8b/10b codeword comprised in the data stream.

4. The method in accordance with claim 1, wherein the one or more delimiters comprise a first delimiter and a second delimiter, and the method further comprises:
appending the first delimiter to a head end of the 8b/10b codeword comprised in the data stream; and
appending the second delimiter to a tail end of the 8b/10b codeword or a tail end of another 8b/10b codeword comprised in the data stream.

5. The method in accordance with claim 4, wherein one bit each of the first delimiter and the second delimiter correspond to a same item of information.

6. The method in accordance with claim 4, wherein one bit each of the first delimiter and the second delimiter correspond to different items of information.

7. The method in accordance with claim 1, wherein each of the one or more delimiters includes a data bit for representing an item of information to be transferred with the data stream and a direct current (DC) balancing bit configured to provide DC balance to the data stream.

8. The method in accordance with claim 1, wherein one of the zero bit or the one bit of a delimiter of the one or more delimiters is a parity bit for the one or more 8b/10b codewords comprised in the data stream.

9. The method in accordance with claim 1, wherein mapping bits into one or more delimiters for the data stream comprises limiting the maximum run-length of a same polarity of bits in an 8b/10b codeword that is adjacent to any of the one or more delimiters to four bits.

10. The method in accordance with claim 9, wherein mapping bits into one or more delimiters for the data stream comprises limiting the maximum run-length of a same polarity of bits in an 8b/10b codeword that is non-adjacent to any of the one or more delimiters to five bits.

11. The method in accordance with claim 1, further comprising determining a number of the one or more delimiters to add to the 8b/10b codeword responsive to one or more of: a number of data bits to be conveyed with the 8b/10b codeword or the data stream comprising the 8b/10b codeword; an importance level of at least one of the bits to be conveyed with the data stream; and an available bandwidth of a communication channel designated for use in transmitting the data stream.

12. A system for coding a data stream, comprising:
a data stream encoder configured to map bits into one or more delimiters for the data stream while limiting a maximum run-length of a same polarity of bits in the data stream to be no more than 5, wherein each of the one or more delimiters comprise a zero bit and a one bit appended to an 8b/10b codeword of one or more 8b/10b codewords in the data stream; and
a transmitter configured to transmit the one or more delimiters in the data stream.

13. The system in accordance with claim 12, wherein the data stream encoder is further configured to append a delimiter of the one or more delimiters to a head end of the 8b/10b codeword comprised in the data stream.

14. The system in accordance with claim 12, further comprising appending a delimiter of the one or more delimiters to a tail end of the 8b/10b codeword comprised in the data stream.

15. The system in accordance with claim 12, wherein the one or more delimiters comprise a first delimiter and a second delimiter, and the data stream encoder is further configured to:
append the first delimiter to a head end of the 8b/10b codeword comprised in the data stream; and
append the second delimiter to a tail end of the 8b/10b codeword or a tail end of another 8b/10b codeword comprised in the data stream.

16. The system in accordance with claim 15, wherein one bit each of the first delimiter and the second delimiter correspond to a same item of information.

17. The system in accordance with claim 15, wherein one bit each of the first delimiter and the second delimiter correspond to different items of information.

18. The system in accordance with claim 12, wherein each of the one or more delimiters includes a data bit for representing an item of information to be transferred with the data stream and a direct current (DC) balancing bit configured to provide DC balance to the data stream.

19. The system in accordance with claim 12, wherein one of the zero bit or the one bit of a delimiter of the one or more delimiters is a parity bit for one or more 8b/10b codewords comprised in the data stream.

20. The system in accordance with claim 12, wherein the data stream encoder is configured to limit the maximum run-length of a same polarity of bits in an 8b/10b codeword that is adjacent to any of the one or more delimiters to four bits.

21. The system in accordance with claim 20, wherein the data stream encoder is configured to limit the maximum run-length of a same polarity of bits in an 8b/10b codeword that is non-adjacent to any of the one or more delimiters to five bits.

22. The system in accordance with claim 12, wherein the data stream encoder is further configured to determine a number of the one or more delimiters to add to the 8b/10b codeword responsive to one or more of: a number of data bits to be conveyed with the 8b/10b codeword or the data stream comprising the 8b/10b codeword; an importance level of at least one of the bits to be conveyed with the data stream; and an available bandwidth of a communication channel designated for use in transmitting the data stream.
